(19) United States
(12) Patent Application Publication
(10) Pub. No.: US 2025/0275335 A1
(43) Pub. Date: Aug. 28, 2025

(54) DISPLAY DEVICE

(71) Applicant: LG ELECTRONICS INC., Seoul (KR)

(72) Inventors: Sangdae PARK, Seoul (KR); Dohyung LEE, Seoul (KR); Sungguk LEE, Seoul (KR); Hwankuk YUH, Seoul (KR); Jaegwang UM, Seoul (KR)

(73) Assignee: LG ELECTRONICS INC., Seoul (KR)

(21) Appl. No.: 18/685,106

(22) PCT Filed: Aug. 18, 2021
(86) PCT No.: PCT/KR2021/010960

§ 371 Date: Jul. 31, 2024

(51) Int. Cl. H10H 29/41; H10H 29/49; H10H 29/855

(52) U.S. Cl. CPC H10H 29/41; H10H 29/49; H10H 29/855

(57) ABSTRACT

The display device can include a substrate, an uneven layer on the substrate, an insulating layer on the uneven layer, and a plurality of semiconductor light emitting devices on the insulating layer. The semiconductor light emitting device can include one of a lateral-type semiconductor light emitting device and a flip-chip type semiconductor light emitting device. The upper surface of the uneven layer has roughness, and the size of the uneven layer is greater than the size of the semiconductor light emitting device.

The embodiment can secure uniform light intensity according to the color viewing angle. In the embodiment, since irregularities are not formed on the lower side of the semiconductor light emitting device, poor adhesion between the semiconductor light emitting device and the substrate can be prevented, reliability can be increased by preventing transfer defect detection errors due to irregularities, and transfer defects can be prevented.

### FIELD

The embodiment relates to a display device.

### DISCUSSION OF THE RELATED ART

A display device displays high-definition image using self-emissive device such as light emitting diodes as a light source for a pixel. The light emitting diode exhibits excellent durability even under harsh environmental conditions and is capable of long lifespan and high luminance, so that they are attracting attention as a light source for next-generation display devices.

Recently, research is in progress to manufacture ultra-small light emitting diodes using highly a material having reliable inorganic crystal structure and dispose them on the panel of a display device (hereinafter referred to as “display panel”) to use them as a light source for a next-generation pixel.

This display device is expanding beyond a flat display into various forms such as a flexible display, a foldable display, a stretchable display, and a rollable display.

In order to realize high resolution, the size of the pixel is gradually becoming smaller, and numerous light emitting devices must be aligned in the smaller pixel, so that that research on the manufacture of ultra-small light emitting diodes as small as micro- or nano-scale is actively taking place.

Research is being conducted to manufacture display devices using a lateral-type semiconductor light emitting device (FIG. 1) or a flip chip-type semiconductor light emitting device.

FIG. 1 is a cross-sectional view showing a conventional semiconductor light emitting device.

As shown in FIG. 1, the lateral-type semiconductor light emitting device has a first electrode 3 and a second electrode 4 disposed in the same direction, that is, toward the upper direction. The first electrode 3 is disposed on the n-type semiconductor layer 1, and the second electrode 4 is disposed on the p-type semiconductor layer 2.

After the p-type semiconductor layer 2 and the active layer are removed to expose the n-type semiconductor layer 1 in the lateral-type semiconductor light emitting device, the first electrode 3 is disposed on the exposed n-type semiconductor layer 1.

Since light is generated in the active layer between the n-type semiconductor layer 1 and the p-type semiconductor layer 2, there is no active layer on the exposed n-type semiconductor layer 1, so that light cannot be generated. Therefore, as shown in FIG. 2, color viewing angle deviation occurs in a lateral-type semiconductor light emitting device (or flip-chip type semiconductor light emitting device). When a display device is manufactured using a lateral-type semiconductor light emitting device, there is a problem in that color viewing angle deviation occurs in each sub-pixel, resulting in deterioration of image quality.

FIG. 2 shows the color viewing angle characteristics on the left and right sides centered on the front of the lateral-type semiconductor light emitting device in FIG. 1. The horizontal axis represents the color viewing angle centered on the front, and the vertical axis represents the intensity of light. In FIG. 2, the light intensity distribution according to the color viewing angle on the right side (0° to 90°) is the light intensity distribution according to the color viewing angle between the front and left sides in the lateral-type semiconductor light emitting device of FIG. 1, and the light intensity distribution according to the color viewing angle on the left side (0° to −90°) is the light intensity distribution according to the color viewing angle between the front and right sides in the lateral-type semiconductor light emitting device of FIG. 1. Since the light generated in the active layer located below the second electrode 4 in FIG. 2 is emitted directly upward, the intensity of light increases depending on the color viewing angle, as shown in the right graph of FIG. 2. On the other hand, in FIG. 2, light cannot be generated without an active layer below the first electrode 3, and the light generated in the active layer located below the second electrode 4 is emitted in the side direction, is reflected by the first electrode 3, etc. to travel toward the upper direction, so that the intensity of light is small depending on the color viewing angle, as shown in the left graph of FIG. 2.

Therefore, in FIG. 2, both the peak value of the light intensity in the left graph and the peak value of the light intensity in the right graph are greater than the peak value of the light intensity in the front. Additionally, since the peak value of the light intensity in the right graph is greater than the peak value of the light intensity in the left graph, a difference occurs between these peak values, resulting in color viewing angle deviation.

In order to reduce the color viewing angle deviation, a method of compensating for color viewing angle in a circuit was proposed, and although this method reduces the color viewing angle deviation, it is not a fundamental solution.

Meanwhile, in order to reduce this color viewing angle deviation, as shown in FIG. 3, irregularities 5 are formed on the lower side of the lateral-type semiconductor light emitting device.

The light generated in the active layer travels downward and is scattered or reflected by the irregularities 5, allowing more light to be emitted onto the first electrode 3, thereby reducing color viewing angle deviation.

However, as shown in FIG. 4, when a lateral-type semiconductor light emitting device 7 with irregularities 5 is disposed on a substrate 8 to manufacture a display device, the following problems occur.

First, since the irregularities 5 are formed on the lower side of the lateral-type semiconductor light emitting device 7, when the lateral-type semiconductor light emitting device 7 is adhered on the substrate 8, due to the irregularities 5, the contact area between the lateral-type semiconductor light emitting device 7 and the substrate 8 is small, causing a problem of poor adhesion.

Second, after the plurality of lateral-type semiconductor light emitting devices 7 on the wafer are transferred onto the substrate 8, transfer defects are detected using a vision inspection device. Normally, when defects such as chip breakage or cracks occur, a black image is displayed.

However, due to the irregularities 5 formed on the lower side of the lateral-type semiconductor light emitting device 7, there is a problem in that a black image is displayed due to irregularities 5, which can be misjudged as a transfer defect. In other words, the reliability of detection of transfer defects decreases.

Third, in order to dispose a plurality of lateral-type semiconductor light emitting device 7 manufactured on the wafer in corresponding sub-pixels of the substrate 8, an alignment key is provided on each of the wafer and the substrate 8, and the alignment process is performed by matching the alignment key of the wafer and the alignment key of the substrate 8.

However, when the unevenness 5 of the lateral-type semiconductor light emitting device 7 is formed, irregularities are also formed on the alignment key, making it difficult to identify the alignment key on the wafer when performing the alignment process, so that there is a problem that transfer defects occur in which the lateral-type semiconductor light emitting device 7 is not accurately transferred within the corresponding sub-pixel.

### SUMMARY OF THE DISCLOSURE

An object of the embodiment is to solve the foregoing and other problems.

Another object of the embodiment is to provide a display device that can secure uniform light intensity according to the color viewing angle.

Another object of the embodiment is to provide a display device that can prevent adhesion failure.

Another object of the embodiment is to provide a display device that can ensure reliability in detecting transfer defects.

Another object of the embodiment is to provide a display device that can prevent transfer defects through accurate alignment.

The technical problems of the embodiments are not limited to those described in this item and include those that can be understood through the description of the invention.

According to one aspect of the embodiment to achieve the above or other objects, a display device, comprising: a substrate; an uneven layer on the substrate; an insulating layer on the uneven layer; and a plurality of semiconductor light emitting devices on the insulating layer, wherein the semiconductor light emitting device comprises one of a lateral-type semiconductor light emitting device and a flip-chip type semiconductor light emitting device, wherein an upper surface of the uneven layer has roughness, and wherein a size of the uneven layer is greater than a size of the semiconductor light emitting device.

The display device can comprise a plurality of gate lines disposed along a first direction on the substrate and a plurality of data lines disposed along a second direction on the substrate, a plurality of sub-pixels can be defined at crossings of the plurality of gate lines and the plurality of data lines, and each of the plurality of semiconductor light emitting devices can be disposed in the sub-pixel.

The sub-pixel can have a driving region where a transistor is disposed and a light emitting region where the semiconductor light emitting device is disposed.

The uneven layer can comprise a plurality of uneven patterns, and the uneven pattern can be disposed on the sub-pixel.

The insulating layer can comprise a plurality of insulating patterns, and the insulating pattern can be disposed on the uneven pattern.

The display device can comprise a first electrode wiring electrically connected to the transistor and one side of the semiconductor light emitting device and a second electrode wiring electrically connected to the other side of the semiconductor light emitting device, and the first electrode wiring can be disposed in a contact hole that penetrates the insulating layer and the uneven layer.

The uneven layer can comprise a first uneven pattern, a second uneven pattern, and a third uneven pattern, the first uneven pattern can be disposed in a first sub-pixel and a first dummy sub-pixel defined along a first stripe column, the second uneven pattern can be disposed in a second sub-pixel and a second dummy sub-pixel defined along a second stripe column, and the third uneven pattern can be disposed on a third sub-pixel and a third dummy sub-pixel defined along a third stripe column.

The insulating layer can be a distributed Bragg reflector (DBR) layer.

The insulating layer can be a planarization layer having a flat upper surface.

The embodiment can secure uniform light intensity according to the color viewing angle.

The semiconductor light emitting device of the embodiment is a lateral-type semiconductor light emitting device or a flip-chip type semiconductor light emitting device, and as a semiconductor light emitting device itself, a light intensity deviation can occur depending on the color viewing angle.

In the embodiment, for example, as shown in FIG. 14, an uneven layer 360 having a size greater than that of the semiconductor light emitting device 150 can be provided on the substrate 310.

Therefore, the light traveling downward from the semiconductor light emitting device 150 can be scattered and/or reflected by the uneven layer 360, thereby changing the color viewing angle generated by the geometric shape or structure of the semiconductor light emitting device 150. By compensating for the light intensity deviation, as shown in FIG. 13, uniform light intensity can be obtained according to the color viewing angle, thereby improving image quality.

In addition, light traveling downward from the semiconductor light emitting device 150 can be scattered and/or reflected by the uneven layer 360, thereby allowing a larger amount of light to travel forward, thereby improving light extraction efficiency.

No irregularities are formed on the lower side of the semiconductor light emitting device 150 of the embodiment. Accordingly, the contact area between the semiconductor light emitting device 150 and the substrate 310 is maximized, and adhesion defects can be prevented. In addition, when detecting transfer defects using a vision inspector, it is possible to prevent errors in detecting transfer defects from occurring due to irregularities formed on the lower side of the semiconductor light emitting device 150, thereby increasing the reliability of detecting transfer defects. In addition, since no irregularities are formed on the lower side of the semiconductor light emitting device 150, the alignment key on the wafer is not damaged, and an accurate alignment process is possible, allowing the semiconductor light emitting device 150 to deviate from the sub-pixel of the substrate 310. Transfer defects can be prevented.

Additional scope of applicability of the embodiments will become apparent from the detailed description below. However, since various changes and modifications within the spirit and scope of the embodiments can be clearly understood by those skilled in the art, the detailed description and specific embodiments, such as preferred embodiments, should be understood as being given by way of example only.

### BRIEF DESCRIPTION OF THE DRAWINGS

FIG. 1 is a cross-sectional view showing a conventional semiconductor light emitting device.

FIG. 2 shows color viewing angle of a conventional semiconductor light emitting device.

FIG. 3 shows irregularities provided on a lower side of the semiconductor light emitting device of FIG. 1.

FIG. 4 is a cross-sectional view showing a display device comprising the semiconductor light emitting device of FIG. 3.

FIG. 5 shows a living room of a house where a display device according to an embodiment is disposed.

FIG. 6 is a block diagram schematically showing a display device according to an embodiment.

FIG. 7 is a circuit diagram showing an example of the pixel of FIG. 6.

FIG. 8 is a plan view showing the display panel of FIG. 6 in detail.

FIG. 9 is an enlarged view of the first panel area in the display device of FIG. 5.

FIG. 10 is a first schematic diagram of a display device according to an embodiment.

FIG. 11 is a second schematic diagram of a display device according to an embodiment.

FIG. 12 is a third schematic diagram of a display device according to an embodiment.

FIG. 13 shows color viewing angle of a display device according to an embodiment.

FIG. 14 is a cross-sectional view showing a display device according to an embodiment.

FIGS. 15 to 19 show a manufacturing process of a display device according to an embodiment.

FIG. 20 is a first example showing the arrangement of a plurality of uneven patterns included in an uneven layer.

FIG. 21 is a second example showing the arrangement of a plurality of uneven patterns included in an uneven layer.

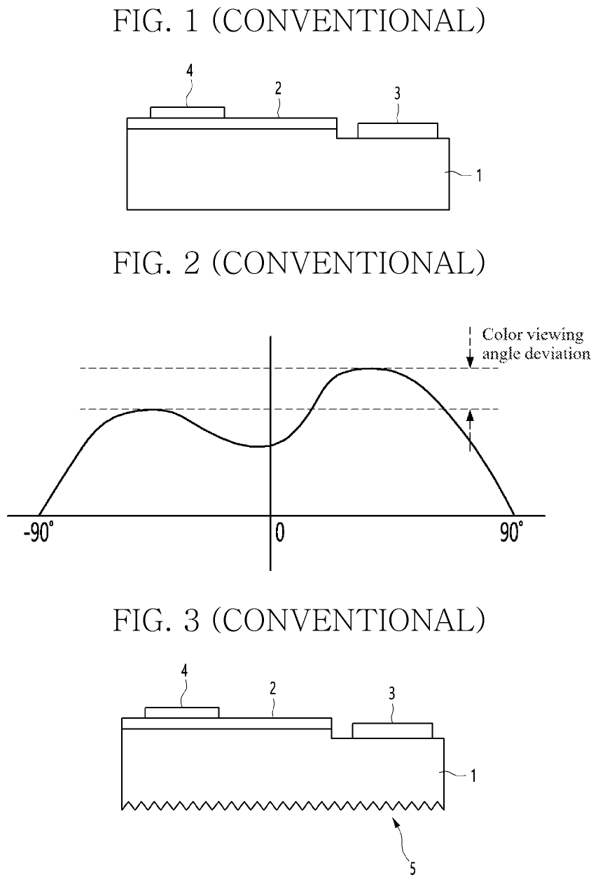

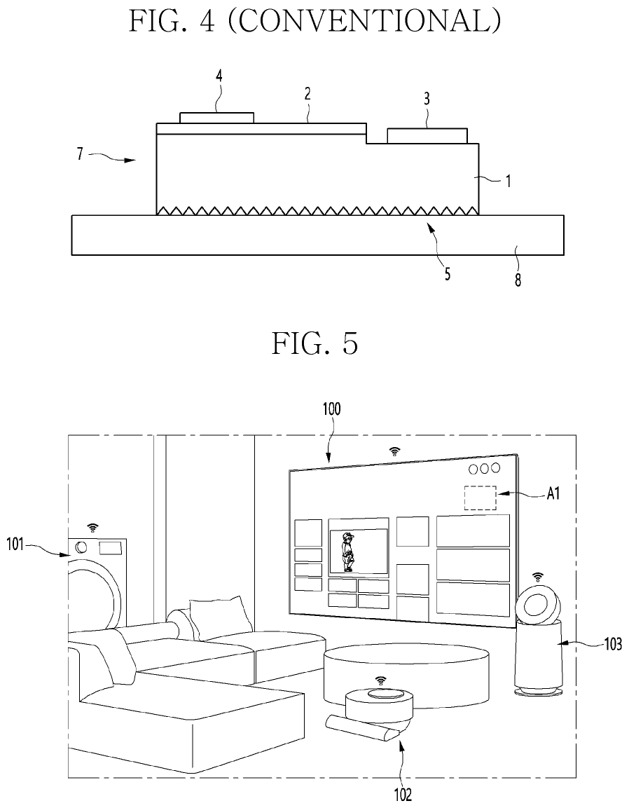

### DETAILED DESCRIPTION OF EMBODIMENTS

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

A display device described in this specification can comprise a TV, a signage, a mobile phone, a smart phone, a head-up display (HUD) for automobiles, a backlight unit for a laptop computer, and a display for VR or AR. etc. However, the configuration according to the embodiment described in this specification can be applied to a device capable of displaying even if it is a new product type that is developed in the future.

Hereinafter, a light emitting device according to the embodiment and a display device including the same will be described.

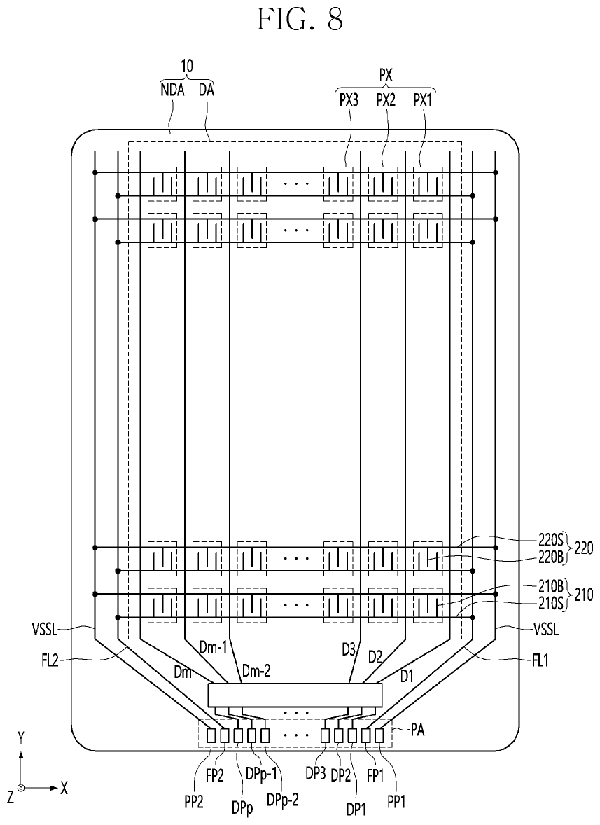

FIG. 5 illustrates a living room of a house, in which a display device is disposed, according to the embodiment.

Referring to FIG. 5, according to the embodiment, a display device 100 can display the status of various electronic devices, such as a washing machine 101, a robot cleaner 102, or an air purifier 103, can make communication with various electronic products based on Internet of Things (IOT), and can control various electronic products based on the setting data of a user.

According to the embodiment, the display device 100 can comprise a flexible display manufactured on a thin and flexible substrate. The flexible display can maintain the characteristic of an existing flat panel display, and can be bendable and rollable, like paper.

Visible information in the flexible display device can be realized by independently controlling the emitting of light from unit pixels arranged in the form of a matrix. The unit pixel is the minimum pixel to realize one color. The unit pixel of the flexible display device can be realized with a light emitting device. According to an embodiment, the light emitting device can comprise, but is not limited to, a micro-LED or a nano-LED.

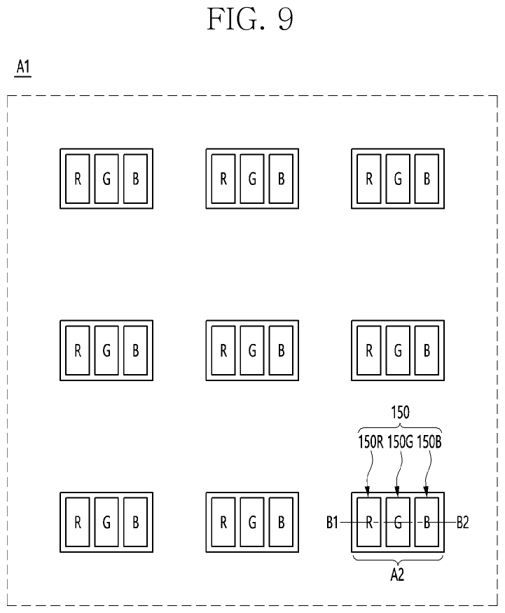

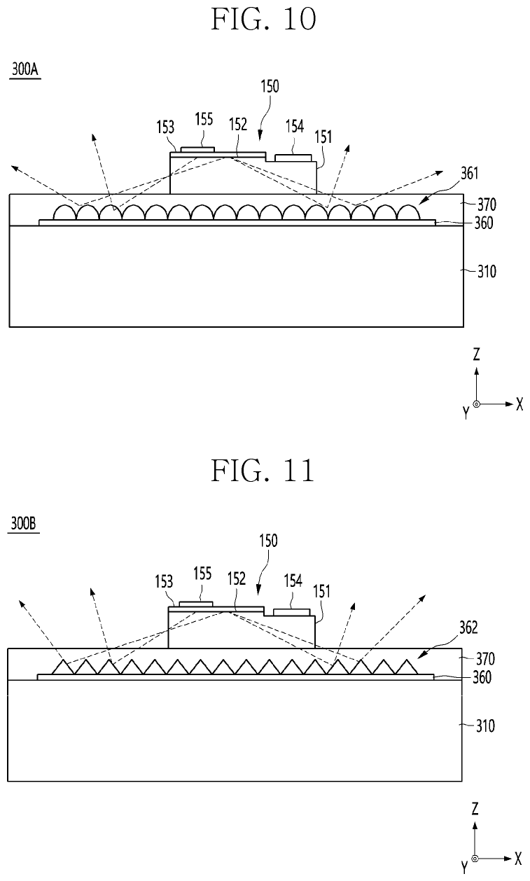

FIG. 6 is a block diagram schematically illustrating a display device according to the embodiment, and FIG. 7 is a circuit diagram illustrating a pixel of FIG. 6.

Referring to FIGS. 6 and 7, according to the embodiment, the display device 100 can comprise a display panel 10, a driving circuit 20, a scan driver 30, and a power supply circuit 50.

According to an embodiment, the display device 100 can drive the light emitting device in an active matrix (AM) manner or a passive matrix (PM) manner.

The driving circuit 20 can comprise a data driver 21 and a timing controller 22.

The display panel 10 can have, but is not limited to, the shape of a rectangle. In other words, the display panel 10 can be formed in a circular shape or an oval shape. At least one side of the display panel 10 can be formed to be bent with a specific curvature.

The display panel 10 can be divided into a display region DA and a non-display region NDA disposed at a peripheral portion of the display region DA. The display region DA has pixels PX formed therein to display an image. The display panel 10 can comprise data lines D1-Dm (m is an integer value equal to or greater than 2), scan lines S1-Sn (n is an integer value equal to or greater than 2) crossing the data lines D1-Dm, a high-potential voltage line to supply a high-potential voltage, a low-potential voltage line to supply a low-potential voltage, and pixels PX connected with the data lines D1-Dm and the scan lines S1-Sn.

Each pixel PX can comprise a first sub-pixel PX1, a second sub-pixel PX2, and a third sub-pixel PX3. The first sub-pixel PX1 can emit first color light having a first main wavelength, the second sub-pixel PX2 can emit second color light having a second main wavelength, and the third sub-pixel PX3 can emit third color light having a third main wavelength. The first color light can be red light, the second color light can be green light, and the third color light can be blue light, but the embodiment is not limited thereto. In addition, although FIG. 6 illustrates that each pixel PX can comprise three sub-pixels, the embodiment is not limited thereto. In other words, each pixel PX can comprise at least four sub-pixels.

Each of the first sub-pixel PX1, the second sub-pixel PX2, and the third sub-pixel PX3 can be connected with at least one of the data lines D1-Dm, at least one of the scan lines S1-Sn, and the high-potential voltage line, respectively. The first sub-pixel PX1 can comprise light emitting devices LD, a plurality of transistors to supply currents to the light emitting devices LD, and at least one capacitor Cst, as illustrated in FIG. 7.

Although not illustrated in the drawings, each of the first sub-pixel PX1, the second sub-pixel PX2, and the third sub-pixel PX3 can comprise only one light emitting device LD and at least one capacitor Cst.

Each of light emitting devices LD can be a semiconductor light emitting diode comprising a first electrode, a plurality of conductivity type semiconductor layers, and a second electrode. In this instance, the first electrode can be an anode electrode, and the second electrode can be a cathode electrode, but the embodiment is not limited thereto.

The light emitting device can be one of a lateral-type light emitting device, a flip chip-type light emitting device, and a vertical-type light emitting device.

A plurality of transistors can comprise a driving transistor DT to supply a current to the light emitting devices LD and a scan transistor ST to supply a data voltage to a gate electrode of the driving transistor DT, as illustrated in FIG. 7. The driving transistor DT can comprise a gate electrode connected with a source electrode of the scan transistor ST, a source electrode connected with a high-potential voltage line to which a high-potential voltage is applied, and a drain electrode connected with first electrodes of the light emitting devices LD. The scan transistor ST can comprise a gate electrode connected with a scan line Sk (k is an integer value satisfying 1≤k≤n), the source electrode connected with the gate electrode of the driving transistor DT, and a drain electrode connected with a data line Dj (j is an integer value satisfying 1≤j≤m).

The storage capacitor Cst is formed between the gate electrode and the source electrode of the driving transistor DT. The storage capacitor Cst is charged with the difference between a gate voltage and a source voltage of the driving transistor DT.

The driving transistor DT and the scan transistor ST can be formed with thin film transistors. In addition, the above description has been made with reference to FIG. 7 while focusing on that the driving transistor DT and the scan transistor ST are realized with p-type metal oxide semiconductor field effect transistors (MOSFET), but the embodiment is not limited thereto. The driving transistor DT and the scan transistor ST can be realized with an N-type MOSFET. In this instance, the positions of a source electrode and a drain electrode can be changed in each of the driving transistor DT and the scan transistor ST.

In addition, in FIG. 7, each of the first sub-pixel PX1, the second sub-pixel PX2, the third sub-pixel PX3 has a 2 transistor 1 capacitor (2T1C) structure having one driving transistor DT, one scan transistor ST, and one capacitor Cst, but the embodiment is not limited thereto. Each of the first sub-pixel PX1, the second sub-pixel PX2, the third sub-pixel PX3 can comprise a plurality of scan transistors ST and a plurality of storage capacitors Cst.

Since the second sub-pixel PX2 and the third sub-pixel PX3 are expressed in the substantially same circuit diagram as that of the first sub-pixel PX1, the details thereof will be omitted below.

The driving circuit 20 outputs signals and voltages for driving the display panel 10. The driving circuit 20 can comprise the data driver 21 and the timing controller 22.

The data driver 21 receives digital video data DATA and a source control signal DCS from the timing controller 22. The data driver 21 converts the digital video data DATA into analog data voltages in response to the source control signal DCS and supplies the analog data voltages to the data lines D1-Dm of the display panel 10.

The timing controller 21 receives the digital video data DATA and timing signals from a host system. The timing signals can comprise a vertical sync signal, a horizontal sync signal, a data enable signal, and a dot clock. The host system can be an application processor of a smartphone or a tablet PC, a monitor, or a system on chip of TV.

The timing controller 22 generates control signals for controlling the operating timing of the data driver 21 and the scan driver 30. The control signals can comprise a source control signal DCS for controlling the operating timing of the data driver 21 and a scan control signal SCS for controlling the operating timing of the scan driver 30.

The driving circuit 20 can be disposed in the non-display region NDA provided at one side of the display panel 10. The driving circuit 20 can be provided in the form of an integrated circuit (IC), and can be mounted in a chip on glass (COG) manner, a chip on plastic (COP) manner, or an ultrasonic wave bonding manner on the display panel 10, but the embodiment is not limited thereto. For example, the driving circuit 20 can be mounted on a circuit board (not illustrated) instead of the display panel 10.

The data driver 21 can be mounted on in a chip on glass (COG) manner, a chip on plastic (COP) manner, or an ultrasonic wave bonding manner on the display panel 10, and the timing controller 21 can be mounted on the circuit board.

The scan driver 30 receives a scan control signal SCS from the timing controller 22. The scan driver 30 generate scan signals in response to the scan control signal SCS and supplies the scan signals to the scan lines S1-Sn of the display panel 10. The scan driver 30, which comprises a plurality of transistors, can be formed in the non-display region NDA of the display panel 10. Alternatively, the scan driver 30 can be provided in the form of the IC. In this instance, the scan driver 30 can be mounted on a flexible gate film attached to another side of the display panel 10.

The circuit board can be attached onto pads provided at one edge of the display panel 10 using an anisotropic conductive film. Due to this, lead lines of the circuit board can be electrically connected with pads. The circuit board can be a flexible film such as a flexible printed circuit board, a printed circuit board, or a chip on film. The circuit board can be bent below the display panel 10. Due to this, one side of the circuit board can be attached to one edge of the display panel 10, and an opposite side of the circuit board can be disposed below the display panel 10 and connected with a system board on which the host system is mounted.

A power supply circuit 50 can generate voltages necessary for driving the display panel 10, based on main power applied from the system board and can apply the voltages to the display panel 10. For example, the power supply circuit 50 can generate a high-potential voltage VDD and a low-potential voltage VSS for driving the light emitting devices LD of the display panel 10, based on the main power, and can supply the high-potential voltage VDD and the low-potential voltage VSS to the high-potential voltage line and the low-potential voltage line of the display panel 10. In addition, the power supply circuit 50 can generate driving voltages for driving the driving circuit 20 and the scan driver 30, based on the main power, and can supply the driving voltages to the driving circuit 20 and the scan driver 30.

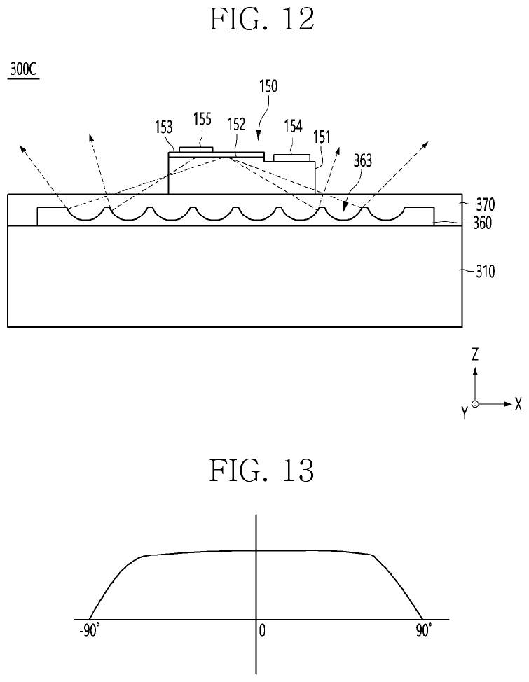

FIG. 8 is a plan view illustrating the display panel of FIG. 6, in detail. FIG. 8 illustrates only data pads DP1-DPp (p is an integer value equal to or greater than 2), floating pads FP1 and FP2, power pads PP1 and PP2, floating lines FL1 and FL2, a low-potential voltage line VSSL, data lines D1-Dm, first pad electrodes 210, and second pad electrodes 220, for the convenience of explanation.

Referring to FIG. 8, the data lines D1-Dm, the first pad electrodes 210, the second pad electrodes 220, and pixels PX can be disposed in the display region DA of the display panel 10.

The data lines D1-Dm can longitudinally extend in a second direction (a Y-axis direction). One sides of the data lines D1-Dm can be connected with the driving circuit 20 (see reference numeral 20 of FIG. 6). Due to this, data voltages of the driving circuit 20 can be applied to the data lines D1-Dm.

The first pad electrodes 210 can be spaced apart from each other by a specific distance in a first direction (an X-axis direction). Due to this, the first pad electrodes 210 may not overlap the data lines D1-Dm. Some first pad electrodes 210, which are disposed at a right edge of the display region DA, of the first pad electrodes 210, can be connected with the first floating line FL1 in the non-display region NDA. Some first pad electrodes 210, which are disposed at a left edge of the display region DA, of the first pad electrodes 210, can be connected with the second floating line FL2 in the non-display region NDA.

Each of the second pad electrodes 220 can longitudinally extend in the first direction (an X-axis direction). Due to this, the second pad electrodes 220 can overlap the data lines D1-Dm. Alternatively, the second pad electrodes 220 can be connected with the low-potential voltage line VSSL in the non-display region NDA. Due to this, a low-potential voltage of the low-potential line VSSL can be applied to the second pad electrodes 220.

The pad part PA, the driving circuit 20, the floating line FL1, the second floating line FL2, and the lower-potential voltage line VSSL can be disposed in the non-display region NDA of the display panel 10. The pad part PA can comprise the data pads DP1-DPp, the floating pads FP1 and FP2, and the power pads PP1 and PP2.

The pad part PA can be disposed at one edge, for example, a lower edge of the display panel 10. The data pads DP1-DPp, the floating pads FP1 and FP2, and the power pads PP1 and PP2 can be arranged in parallel to each other in the first direction (the X-axis direction).

The circuit board can be attached onto the data pads DP1-DPp, the floating pads FP1 and FP2, and the power pads PP1 and PP2 using an anisotropic conductive film. Due to this, the circuit board can be electrically connected with the data pads DP1-DPp, the floating pads FP1 and FP2, and the power pads PP1 and PP2.

The driving circuit 20 can be connected with the data pads DP1-DPp through link lines. The driving circuit 20 can receive the digital video data DATA and the timing signals through the data pads DP1-DPp. The driving circuit 20 can convert the digital video data DATA into the analog data voltages and can supply the analog data voltages to the data lines D1-Dm of the display panel 10.

The low-potential voltage line VSSL can be connected with the first power pad PP1 and the second power pad PP2 of the pad part PA. The low-potential voltage line VSSL can longitudinally extend in the second direction (the Y-axis direction) in portions of the non-display region NDA, which are positioned at a left outer portion and a right outer portion of the display region DA. The low-potential voltage line VSSL can be connected with the second pad electrodes 220. Due to this, the low-potential voltage of the power supply circuit 50 can be applied to the second pad electrodes 220 through the circuit board, the first power pad PP1, the second power pad PP2, and the low-potential voltage line VSSL.

The first floating line FL1 can be connected with the first floating pad FP1 of the pad part PA. The first floating line FL1 can longitudinally extend in the second direction (the Y-axis direction) in portions of the non-display region NDA, which are positioned at the left outer portion and the right outer portion of the display region DA. The first floating pad FP1 and the first floating line FL1 can be a dummy pad and a dummy line having no voltage applied thereto.

The second floating line FL2 can be connected with the second floating pad FP2 of the pad part PA. The second floating line FL2 can longitudinally extend in the second direction (the Y-axis direction) in portions of the non-display region NDA, which are positioned at the left outer portion and the right outer portion of the display region DA. The second floating pad FP2 and the second floating line FL2 can be a dummy pad and a dummy line having no voltage applied thereto.

Meanwhile, since the light emitting devices (see reference sign LD of FIG. 7) have significantly small sizes, the mounting of the light emitting devices LD in the first sub-pixel PX1, the second sub-pixel PX2, and the third sub-pixel PX3 of each pixel PX can be significantly difficult.

To solve the above problem, an alignment technique based on a dielectrophoresis manner has been suggested.

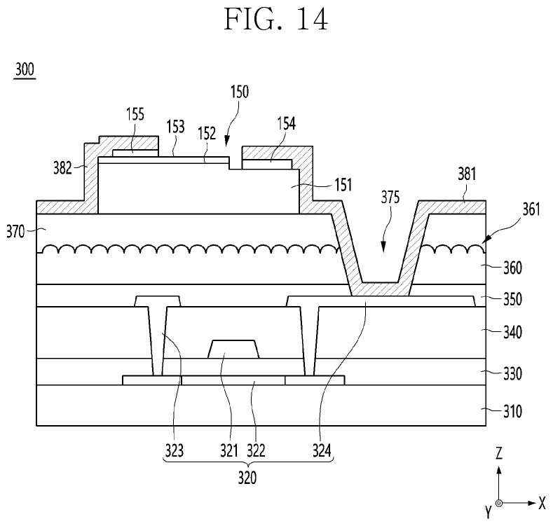

In other words, an electric field can be formed in the first sub-pixel PX1, the second sub-pixel PX2, and the third sub-pixel PX3 of each pixel PX to align the light emitting devices (see reference numeral 150 of FIG. 9) in the manufacturing process of the display panel 10. In addition, the light emitting devices (see reference numeral 150 of FIG. 9) can be aligned in the first sub-pixel PX1, the second sub-pixel PX2, and the third sub-pixel PX3 by applying dielectrophoretic force to light emitting devices (see reference numeral 150 of FIG. 9) through a dielectrophoresis manner during the manufacturing process.

However, during the manufacturing process, it is difficult to drive thin film transistors and apply a ground voltage to the first pad electrodes 210.

Accordingly, although the first pad electrodes 210 are spaced apart from each other by a specific distance in the first direction (the X-axis direction) in the manufactured display device, the first pad electrodes 210 can longitudinally extend without disconnected in the first direction (the X-axis direction).

Due to this, the first pad electrodes 210 can be connected with the first floating line FL1 and the second floating line FL2 during the manufacturing process. Accordingly, the first pad electrodes 210 can receive the ground voltage through the first floating line FL1 and the second floating line FL2. The first pad electrodes 210 can be spaced apart from each other by a specific distance in the first direction (the X-axis direction) by disconnecting the first pad electrodes 210 after aligning the light emitting devices (see reference numeral 150 of FIG. 9) using the dielectrophoresis manner during the manufacturing process.

Meanwhile, the first floating line FL1 and the second floating line FL2 are lines for applying the ground voltage during the manufacturing process. However, any voltage is not applied in the manufactured display device. The ground voltage can be applied to the first floating line FL1 and the second floating line FL2 to prevent static electricity or to drive the light emitting device (see reference numeral 150 of FIG. 9) in the c manufactured display device.

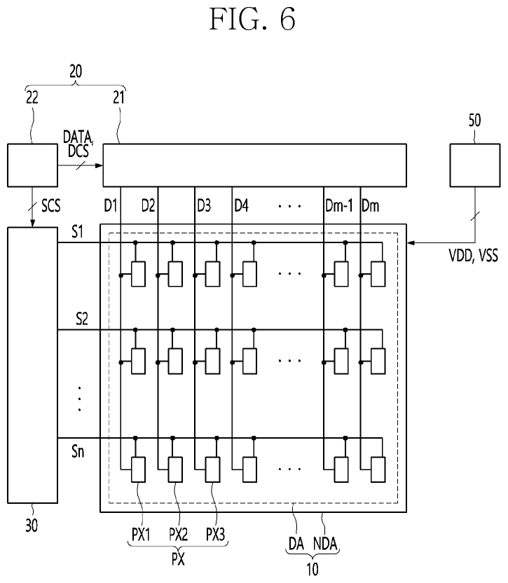

FIG. 9 is an expanded view of a first panel region in the display device of FIG. 3.

Referring to FIG. 9, according to the embodiment, the display device 100 manufactured, as a plurality of panel regions, such as a first panel region Al, are mechanically or electrically connected with each other through tiling.

The first panel region Al can comprise a plurality of light emitting devices 150 arranged according to unit pixels (reference numeral PX of FIG. 6).

For example, each pixel PX can comprise a first sub-pixel PX1, a second sub-pixel PX2, and a third sub-pixel PX3. For example, a plurality of red light emitting device 150R can be disposed in the first sub-pixel PX1, a plurality of green light emitting devices 150G can be disposed in the second sub-pixel PX2, and a plurality of blue light emitting devices 150B can be disposed in the third sub-pixel PX3. The unit pixel PX can further comprise a fourth sub-pixel having no the light emitting device, but the embodiment is not limited thereto.

The embodiment relates to a display device using a lateral-type semiconductor light emitting device (or flip-chip type semiconductor light emitting device).

Hereinafter, the description will be limited to the lateral-type semiconductor light emitting device, but the embodiment can be equally applied to the flip-chip type semiconductor light emitting device.

According to the embodiment, uniform light intensity according to the color viewing angle can be secured without forming irregularities on the lower side of the lateral-type semiconductor light emitting device. That is, an uneven layer that can scatter and/or reflect light can be provided on the substrate. Accordingly, the light generated from the lateral-type semiconductor light emitting device can be scattered and/or reflected by the uneven layer and travels in various directions, so that uniform light intensity according to the color viewing angle can be obtained.

Since there is no need to form irregularities on the lower side of the lateral-type semiconductor light emitting device, there are the following technical advantages.

First, since the lower side of the lateral-type semiconductor light emitting device has a flat surface, the contact area between the lateral-type semiconductor light emitting device and the substrate can be maximized to prevent adhesion defects.

Second, since the lower side of the lateral-type semiconductor light emitting device does not have irregularities, the vision inspection machine does not display a black image due to irregularities as in the prior art, so that the reliability of detecting transfer defects can be increased.

Thirdly, since there is no need to form irregularities on the lower side of the lateral-type semiconductor light emitting device, no damage occurs to the alignment key on the wafer, and an accurate alignment process is possible, so that transfer defects in which the lateral-type semiconductor light emitting device is transferred beyond the sub-pixel of the substrate can be prevented.

Below, a display device according to an embodiment will be described with reference to various drawings.

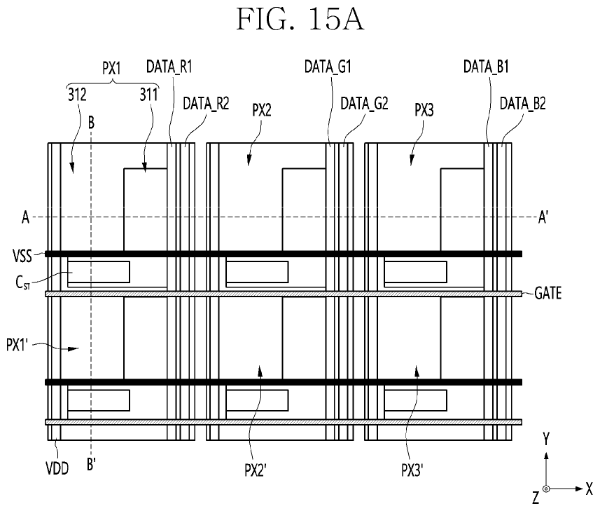

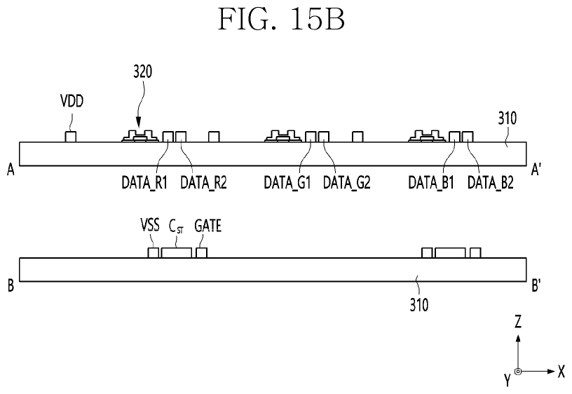

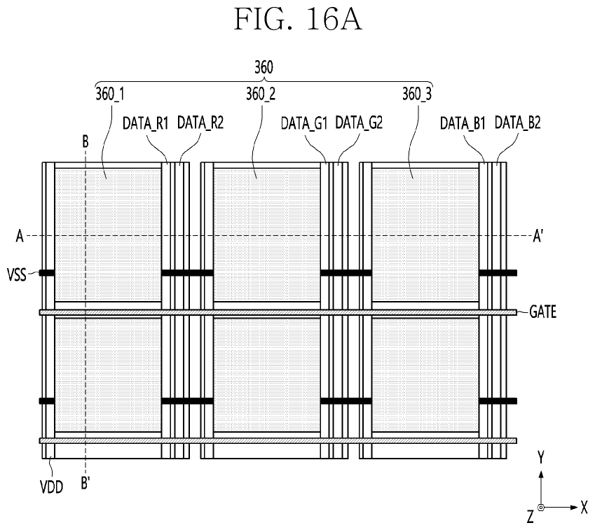

FIG. 10 is a first schematic diagram of a display device according to an embodiment. FIG. 11 is a second schematic diagram of a display device according to an embodiment. FIG. 12 is a third schematic diagram of a display device according to an embodiment.

The remaining structures of the display devices 300A, 300B, and 300C shown in FIGS. 10 to 12 are the same except for the uneven layer 360. That is, the uneven layer 360 can be disposed on the substrate 310, the insulating layer 370 can be disposed on the uneven layer 360, and the semiconductor light emitting device 150 can be disposed on the insulating layer 370. The semiconductor light emitting device 150 is a lateral-type semiconductor light emitting device, but can also be a flip-chip type semiconductor light emitting device.

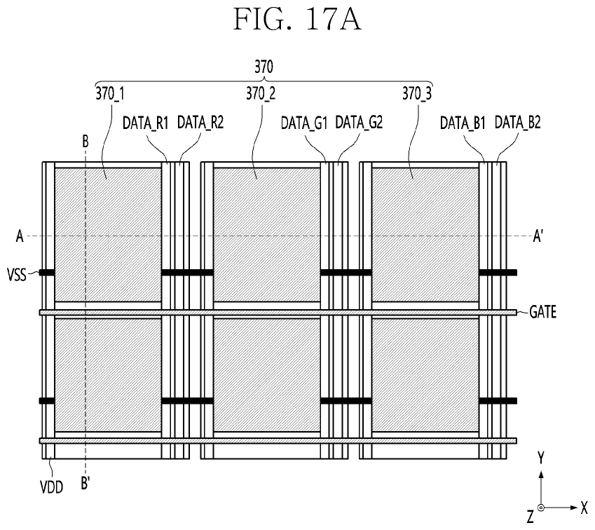

FIGS. 10 to 12 schematically show display devices 300A, 300B, and 300C, and numerous components are omitted. For example, at least two or more transistors and at least one capacitor can be provided, and a plurality of insulating layers (330 to 350 in FIG. 14) can be provided to form these transistors and capacitor. For example, at least two transistors and at least one capacitor can be disposed between the substrate 310 and the uneven layer 360, but is not limited thereto.

As shown in FIG. 10, the uneven layer 360 can comprise roughness 361. For example, the roughness 361 can be formed on an upper surface of the uneven layer 360, but is not limited thereto. The roughness 361 can have a plurality of protrusions that are convex toward the upper direction, but is not limited thereto. For example, the protrusions can have a round shape that is convex toward the upper direction.

The plurality of protrusions can be disposed in contact with each other or spaced apart from each other. The roughness 361 can be formed integrally with the uneven layer 360 or can be formed separately. For example, the upper surface of the uneven layer 360 can be partially removed to form roughness 361. For example, a base member can be formed on the uneven layer 360 and the roughness 361 can be formed by partially removing the base member. The base member can be formed of the same material as the uneven layer 360, but is not limited thereto.

As shown in FIG. 11, the uneven layer 360 can comprise roughness 362. For example, the roughness 362 can be formed on an upper surface of the uneven layer 360, but is not limited thereto. The roughness 362 can have a plurality of protrusions that are convex toward the upper direction, but is not limited thereto. For example, a protrusion can have at least three or more inclined surfaces centered on a vertex.

The plurality of protrusions can be disposed in contact with each other or spaced apart from each other. The roughness 362 can be formed integrally with the uneven layer 360 or can be formed separately.

As shown in FIG. 12, the uneven layer 360 can comprise roughness 363. For example, the roughness 363 can be formed on an upper surface of the uneven layer 360, but is not limited thereto. The roughness 363 can have a plurality of protrusions concave in the downward direction, but is not limited thereto. For example, the protrusion can have a round shape that is concave downward.

A plurality of protrusions can be disposed in contact with each other or spaced apart from each other. The roughness 363 can be formed integrally with the uneven layer 360 or can be formed separately.

Although not shown, various shapes of roughness are possible.

In FIGS. 10 to 12, the uneven layer 360 can be a reflective layer capable of reflecting light. The uneven layer 360 and/or the roughnesses 361 to 363 can be formed of a reflective metal. For example, the uneven layer 360 and/or the roughnesses 361 to 363 can be Ag, Al, Ti, Cr, Pb, etc., or alloys thereof.

In FIGS. 10 to 12, light traveling downward from the semiconductor light emitting device 150 can be scattered and/or reflected by the uneven layer 360, thereby improving the color viewing angle and improving light extraction efficiency.

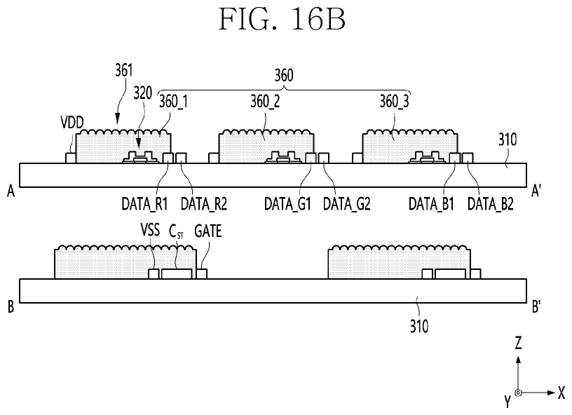

That is, as shown in FIG. 13, even if no irregularities are formed on the lower side of the semiconductor light emitting device 150, light traveling downward from the semiconductor light emitting device 150 can be scattered and/or reflected by the uneven layer 360 provided on the substrate 310, so that uniform light intensity can be obtained at a color viewing angle between −90° and 90°, thereby improving color viewing angle to improve image quality. In addition, light extraction efficiency can be improved by the uneven layer 360, resulting in higher luminance, so that high-luminance display can be possible.

Meanwhile, since the size of the uneven layer 360 is greater than the size of the semiconductor light emitting device 150, light traveling diagonally downward from the active layer of the semiconductor light emitting device 150 can be scattered and/or reflected by the uneven layer 360, so that it is possible to secure uniform light intensity according to the color viewing angle and improve light extraction efficiency. For example, the uneven layer 360 can be disposed to have the maximum area within the sub-pixel.

Meanwhile, the insulating layer 370 can be disposed on the uneven layer 360.

As an example, the insulating layer 370 can be a planarization layer with a flat upper surface. Since the upper surface is flat, the contact area between the upper surface of the insulating layer 370 and the semiconductor light emitting device 150 can be maximized, so that the semiconductor light emitting device 150 can be more easily adhered to the insulating layer 370, thereby preventing adhesion defects.

As another example, the insulating layer 370 can be a distributed Bragg reflector (DBR) layer. The insulating layer 370 can have a structure in which media with different refractive indices are stacked on top of each other. For example, the insulating layer 370 can have a structure in which SiOx or TiOx are stacked on each other, but is not limited thereto.

Accordingly, light traveling downward from the semiconductor light emitting device 150 can be reflected by the laminated medium of the insulating layer 370. For example, part of the light can be reflected from a first medium layer of the insulating layer 370, and another part of the light can be reflected from a second medium layer of the insulating layer 370. In this way, as light is reflected from different media layers, light can be reflected and dispersed in different directions, so that uniform light intensity according to the color viewing angle can be obtained.

Meanwhile, the semiconductor light emitting device 150 can comprise a first conductivity type semiconductor layer 151, an active layer 152, a second conductivity type semiconductor layer 153, a first electrode 154, and a second electrode 155.

The first conductivity type semiconductor layer 151, the active layer 152, and the second conductivity type semiconductor layer 153 can comprise a group II-IV compound or a group III-V compound, but are not limited thereto. For example, the first conductivity type semiconductor layer 151 can comprise an n-type dopant, and the second conductivity type semiconductor layer 153 can comprise a p-type dopant, but are not limited thereto.

The first electrode 154 can be disposed on the first conductivity type semiconductor layer 151, and the second electrode 155 can be disposed on the second conductivity type semiconductor layer 153. The first electrode 154 and the second electrode 155 are made of metal and can consist of at least one layer.

The semiconductor light emitting device 150 can be a lateral-type semiconductor light emitting device or a flip-chip type semiconductor light emitting device, and the first electrode 154 and the second electrode 155 can be disposed toward the same direction. To this end, the second conductivity type semiconductor layer 153 and the active layer 152 can be removed so that an upper surface of the first conductivity type semiconductor layer 151 is exposed. The first electrode 154 can be disposed on the exposed upper surface of the first conductivity type semiconductor layer 151.

FIG. 14 is a cross-sectional view showing a display device according to an embodiment.

The uneven layer 360 shown in FIG. 14 can be the uneven layer 360 shown in FIG. 10, and in addition to the uneven layer 360 shown in FIGS. 11 and 12, various uneven layers not shown can be equally adopted in the embodiment.

Referring to FIG. 14, the display device 300 according to the embodiment can comprise a substrate 310, a plurality of insulating layers 330, 340, 350, and 370, a transistor 320, an uneven layer 360, and a semiconductor light emitting device 150. The display device 300 according to an embodiment can comprise more components than these.

FIG. 14 is a cross-sectional view of a single sub-pixel, and a plurality of sub-pixels defined on the substrate 310 can have the same structure as that of FIG. 14.

The substrate 310 can be a support member that supports components disposed on the substrate 310 or a protection member that protects the components.

The substrate 310 can be a rigid substrate or a flexible substrate. The substrate 310 can be made of glass or polyimide. Additionally, the substrate 310 can comprise a flexible material such as a polyethylene naphthalate (PEN) or a polyethylene terephthalate (PET). Additionally, the substrate 310 can be made of a transparent material, but is not limited thereto.

The transistor 320 can be a driving transistor. For example, the transistor 320 can be the driving transistor DT shown in FIG. 7. The transistor 320 can comprise a PMOS transistor or an NMOS transistor.

Although not shown in the drawing, the scan transistor ST shown in FIG. 7 can be disposed on the substrate 310 and electrically connected to the transistor 320. Although not shown in the drawing, a capacitor Cst shown in FIG. 7 can be formed on the substrate 310.

The transistor 320 can comprise a gate electrode 321, a channel layer 322, a source electrode 323, and a drain electrode 324. The channel layer 322 can be conducted by a voltage applied to the gate electrode 321, so that the source electrode 323 and the drain electrode 324 can be electrically connected. Accordingly, the signal applied to the source electrode 323 can be supplied to the semiconductor light emitting device 150 through the drain electrode 324.

In an embodiment, the transistor 320 can be a top gate type transistor. The top gate transistor 320 can have a structure in which the gate electrode 321 is located on the channel layer 322. The transistor 320 of the embodiment can be a bottom gate type transistor.

For example, the channel layer 322 can be disposed on the substrate 310, and the insulating layer 330 can be disposed on the channel layer 322. The gate electrode 321 can be disposed on the insulating layer 330, and the insulating layer 340 can be disposed on the gate electrode 321. The source electrode 323 and the drain electrode 324 can be disposed on the insulating layer 340, and the insulating layer 350 can be disposed on the source electrode 323 and the drain electrode 324.

The insulating layers 330, 340, and 350 can be formed of an inorganic material or an organic material. Each of the insulating layers 330, 340, and 350 can be a planarization layer having a flat upper surface. In this instance, the channel layer 322, gate electrode 321, source electrode 323, or drain electrode 324 can be easily formed on the upper surface of each of the insulating layers 330, 340, and 350.

The insulating layer 330 can be referred to as a first insulating layer, the insulating layer 340 can be referred to as a second insulating layer, the insulating layer 350 can be referred to as a third insulating layer, and the insulating layer 370 can be referred to as a fourth insulating layer, but are not limited thereto.

The uneven layer 360 can be disposed on the insulating layer 350. The uneven layer 360 can be one of the uneven layers 360 shown in FIGS. 10 to 12.

The insulating layer 370 can be disposed on the uneven layer 360.

Since the uneven layer 360 and the insulating layer 370 have been previously described, detailed descriptions are omitted.

In an embodiment, the uneven layer 360 and/or the insulating layer 370 can be formed for each sub-pixel PX1, PX1′, PX2, PX2′, PX3, and PX3′. That is, the uneven layer 360 and/or the insulating layer 370 can be disposed to be spaced apart from each other between the sub-pixels PX1, PX1′, PX2, PX2′, PX3, and PX3′. For example, the uneven layer 360 disposed in the first sub-pixel PX1 can be spaced apart from the uneven layer 360 disposed in the second sub-pixel PX2. For example, the insulating layer 370 disposed in the first sub-pixel PX1 can be spaced apart from the insulating layer 370 disposed in the second sub-pixel PX2.

In the drawing, the sub-pixels PX1, PX1′, PX2, PX2′, PX3, and PX3′ have a rectangular shape, but can also have a triangle, square, circle, or polygon.

Light traveling downward from the semiconductor light emitting device 150 can be scattered and/or reflected by the uneven layer 360, so that uniform light intensity can be obtained depending on the color viewing angle and light extraction efficiency can be improved.

Light traveling downward from the semiconductor light emitting device 150 can be reflected by different medium layers of the insulating layer 370, so that uniform light intensity can be obtained depending on the color viewing angle and light extraction efficiency can be improved.

The contact area between the semiconductor light emitting device 150 and the insulating layer 370 can be maximized, so that adhesion defects can be prevented.

The semiconductor light emitting device 150 can be disposed on the insulating layer 370. Although not shown, the semiconductor light emitting device 150 can be attached to the upper surface of the insulating layer 370 using an adhesive.

The semiconductor light emitting device 150 can be a lateral-type semiconductor light emitting device or a flip-chip type semiconductor light emitting device.

Meanwhile, as the second conductive semiconductor layer 153 and the active layer 152 are removed for placement of the first electrode 154, the active layer 152 can be disposed below the second electrode 155, so that light can be generated in the active layer 152, but there is no active layer 152 below the first electrode 154, so light may not be generated. Accordingly, more of the light generated in the active layer 152 can be emitted in the upward direction, and less is emitted in the upward direction corresponding to the first electrode 154. Accordingly, different light intensities can be obtained depending on the viewing angle in front of the semiconductor light emitting device 150, that is, the color viewing angle. That is, different light intensity deviations can occur depending on the color viewing angle. This deviation in light intensity can cause deterioration in image quality.

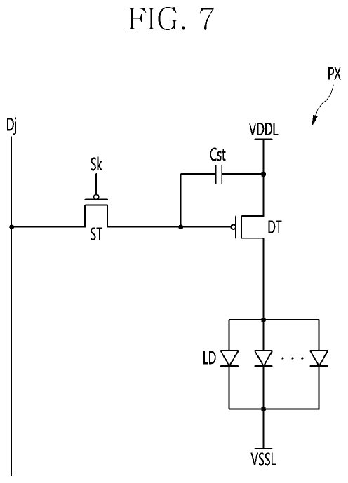

Meanwhile, as shown in FIG. 3, in order to reduce the deviation in light intensity depending on the color viewing angle, irregularities 5 can be formed on the lower side of the semiconductor light emitting device. However, as shown in FIG. 4, when the semiconductor light emitting device 7 with irregularities 5 formed on the lower side is transferred onto the substrate 8, adhesion failure occurs, when detecting transfer defects, detection errors caused by irregularities 5 cause a decrease in reliability, and damage to the alignment key when irregularities are formed may result in transfer defects due to alignment errors during the alignment process.

In the embodiment, as shown in FIG. 14, no irregularities are formed on the lower side of the semiconductor light emitting device 150. That is, the lower surface of the semiconductor light emitting device 150 can have a flat surface. The upper surface of the insulating layer 370 corresponding to the lower surface of the semiconductor light emitting device 150 can also have a flat surface. Accordingly, the contact area between the semiconductor light emitting device 150 and the insulating layer 370 can be maximized, so that adhesion failure can be prevented.

In addition, since no irregularities are formed on the lower side of the semiconductor light emitting device 150 in the embodiment, reliability can be improved because detection errors due to irregularities do not occur when detecting transfer defects.

In addition, since no irregularities are formed on the lower side of the semiconductor light emitting device 150 in the embodiment, a more accurate alignment process is possible, so that transfer defects can be prevented.

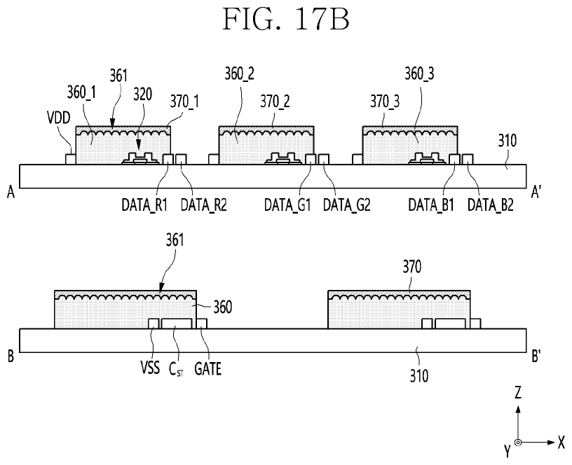

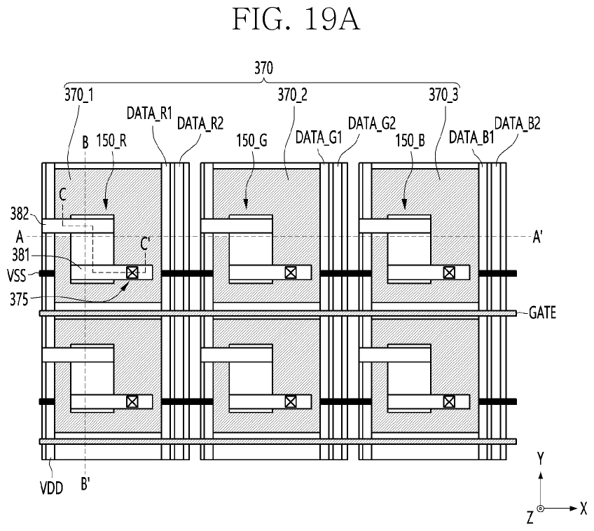

Hereinafter, with reference to FIGS. 15 to 19, a method of manufacturing a display device 300 having a plurality of sub-pixels by expanding the unit sub-pixel shown in FIG. 14 will be described.

FIGS. 15 to 19 show a manufacturing process of a display device according to an embodiment.

As shown in FIGS. 15A and 15B, a plurality of gate lines GATE, a plurality of data lines DATA_R1, DATA_R2, DATA_G1, DATA_G2, DATA_B1, and DATA_B2, and a plurality of first power line VDD, a plurality of second power lines VSS, and a capacitor Cst.

For example, the plurality of gate lines GATE and the plurality of second power lines VSS can be formed along a first direction X, and the plurality of data lines DATA_R1, DATA_R2, DATA_G1, DATA_G2, DATA_B1, and DATA_B2 and the plurality of first power lines VDD can be formed along a second direction Y, but are not limited thereto.

For example, a high potential voltage can be supplied to the first power line VDD, and a low potential voltage can be supplied to the second power line VSS. The first power line VDD can be the high potential line VDDL shown in FIG. 7, and the second power line VSS can be the low potential line VSSL shown in FIG. 7. The high potential voltage can be tens of volts, and the low potential voltage can be 0 volts or lower.

The gate line GATE and the data lines DATA_R1, DATA_R2, DATA_G1, DATA_G2, DATA_B1, and DATA_B2 can intersect. When the gate line GATE and the data lines DATA_R1, DATA_R2, DATA_G1, DATA_G2, DATA_B1, and DATA_B2 can be formed on the same layer, since the gate line GATE and the data lines DATA_R1, DATA_R2, DATA_G1, DATA_G2, DATA_B1, and DATA_B2 can cross each other, an electrical short can occur. To prevent such an electrical short, although not shown, the gate line GATE or the data lines DATA_R1, DATA_R2, DATA_G1, DATA_G2, DATA_B1, and DATA_B2 can be disconnected at the point where they intersect, and the disconnected gate line GATE or the data lines DATA_R1, DATA_R2, DATA_G1, DATA_G2, DATA_B1, and DATA_B2 can be electrically connected using a connection electrode formed on a different layer from the gate line GATE or the data lines DATA_R1, DATA_R2, DATA_G1, DATA_G2, DATA_B1, and DATA_B2.

For example, the gate line GATE and the data lines DATA_R1, DATA_R2, DATA_G1, DATA_G2, DATA_B1, and DATA_B2 can be formed on the same layer as the gate electrode 321 of the transistor 320 with the top gate type, and the connection electrode can be formed on the same layer as the source electrode 323 and the drain electrode 324 of the transistor 320, but is not limited thereto.

The sub-pixels PX1, PX1′, PX2, PX2′, PX3, and PX3′ can be defined at crossings of the gate line GATE and the data lines DATA_R1, DATA_R2, DATA_G1, DATA_G2, DATA_B1, and DATA_B2. Therefore, by crossing the gate line GATE and the data lines DATA_R1, DATA_R2, DATA_G1, DATA_G2, DATA_B1, and DATA_B2, the plurality of sub-pixels PX1, PX1′, PX2, PX2′, PX3, and PX3′ can be formed in a matrix form. That is, the plurality of sub-pixels PX1, PX1′, PX2, PX2′, PX3, and PX3′ can be formed along the first direction X, while they can be formed along the second direction Y.

The capacitor Cst can be formed by a dielectric layer and metal films formed above and below the dielectric layer. In the drawing, the capacitor Cst is shown on the same layer as the gate line GATE and the data lines DATA_R1, DATA_R2, DATA_G1, DATA_G2, DATA_B1, and DATA_B2, this is shown for convenience of explanation, and for example, the lower metal film of the capacitor Cst can be formed on the same layer as the gate line GATE and the data lines DATA_R1, DATA_R2, DATA_G1, DATA_G2, DATA_B1, and DATA_B2. In this instance, a dielectric layer (or insulating layer) can be formed on the gate line GATE and the data lines DATA_R1, DATA_R2, DATA_G1, DATA_G2, DATA_B1, and DATA_B2, and an upper metal film can be formed on the dielectric layer, thereby forming a capacitor Cst. For example, as shown in FIG. 14, the lower metal film can be formed on the same layer as the gate electrode 321 of the top gate transistor 320, and the upper metal film can be formed on the same layer as the source electrode 323 and the drain electrode 324. In this instance, the dielectric layer can be the insulating layer 340 shown in FIG. 14.

Although not shown, the insulating layer 330 and the channel layer 322 shown in FIG. 14 can be formed below the gate line GATE and the data lines DATA_R1, DATA_R2, DATA_G1, DATA_G2, DATA_B1, and DATA_B2.

As shown in FIG. 15A, each of the plurality of sub-pixels PX1, PX1′, PX2, PX2′, PX3, and PX3′ can have a driving region 311 and a light emitting region 312. For example, the driving region 311 can be a region where devices for driving the semiconductor light emitting device 150, for example, at least two transistors ST and DT and a capacitor Cst shown in FIG. 7 can be formed. For example, the light emitting region 312 can be a region where at least one semiconductor light emitting device 150 is formed to emit light. The proportion of the pixel region occupied by the light emitting region 312 can be aperture ratio, and the larger the aperture ratio, the higher the luminance can be obtained. In order to increase the aperture ratio, the size of the driving region 311 can be reduced and the size of the light emitting region 312 can be increased. The driving region 311 can be defined within the sub-pixel PX1, PX1′, PX2, PX2′, PX3, and PX3′, or be defined in a portion of the sub-pixels PX1, PX1′, PX2, PX2′, PX3, and PX3′ and a region between the sub-pixels PX1, PX1′, PX2, PX2′, PX3, and PX3′. PX1′, PX2′, and PX3′ can be dummy sub-pixels of PX1, PX2, and PX3, respectively, and can emit light as a replacement when the semiconductor light emitting device 150 formed in each of PX1, PX2, and PX3 have lighting defects. For example, when the semiconductor light emitting device 150 formed in the first sub-pixel PX1 has a lighting defect, the semiconductor light emitting device 150 formed in the first dummy sub-pixel PX1′ can emit light. To this end, the semiconductor light emitting devices 150 formed in each of PX1 and PX1′ can generate the same color light, the semiconductor light emitting devices 150 formed in each of PX2 and PX2′ can generate the same color light, and the semiconductor light emitting devices 150 formed in each of PX3 and PX3′ can generate the same color light. For example, the red semiconductor light emitting device 150_R formed in each of PX1 and PX1′ can generate red light, the green semiconductor light emitting device 150_G formed in each of PX2 and PX2′ can generate green light, and the blue semiconductor light emitting device 150_B formed in each of PX3 and PX3′ can generate blue light, but is not limited thereto.

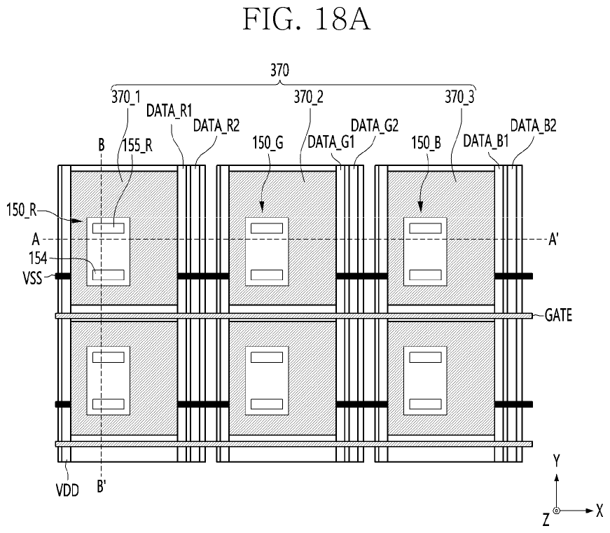

As shown in FIGS. 16A and 16B, the uneven layer 360 can be formed on the gate line GATE and the data lines DATA_R1, DATA_R2, DATA_G1, DATA_G2, DATA_B1, and DATA_B2.

The transistor 320 can be formed before the uneven layer 360 is formed. In FIGS. 16A and 16B, as a bottom gate type transistor 320, a gate electrode 321 can be formed first, a channel layer 322 can be formed thereon, and a source electrode 323 and a drain electrode 324 can be formed thereon. In the case of the bottom gate type transistor 320, the gate electrode 321 can be formed on the same layer as the gate line GATE and the data lines DATA_R1, DATA_R2, DATA_G1, DATA_G2, DATA_B1, and DATA_B2, and the source electrode 323 and the drain electrode 324 can be formed on the same layer as the connection electrode.

After the transistor 320 is formed, an insulating layer (350 in FIG. 14) can be formed on the transistor 320, and an uneven layer 360 can be formed on the insulating layer 350.

The uneven layer 360 can comprise a plurality of uneven patterns 360_1, 360_2, and 360_3. For example, each of the plurality of uneven patterns 360_1, 360_2 and 360_3 can be disposed in a sub-pixel PX1, PX1′, PX2, PX2′, PX3, and PX3′. For example, each of the plurality of uneven patterns 360_1, 360_2, and 360_3 can be disposed to be spaced apart from each other between the sub-pixels PX1, PX1′, PX2, PX2′, PX3, and PX3′.

When the uneven layer 360 is formed of metal, the uneven layer 360 can be electrically connected to the semiconductor light emitting device 150 in each sub-pixel PX1, PX1′, PX2, PX2′, PX3, and PX3′. Since the connected first electrode wiring (381 in FIG. 14) is electrically short-circuited, the driving current can become the same, so that brightness control becomes impossible. Accordingly, the uneven layer 360 disposed in each sub-pixel PX1, PX1′, PX2, PX2′, PX3, and PX3′, that is, the first uneven pattern 360_1, the second uneven pattern 360_2, and the third uneven layer 360_3 can be spatially spaced apart from each other and electrically disconnected.

For example, when the uneven layer 360 is electrically insulated, the uneven layer 360 can be formed integrally with a plurality of sub-pixels PX1, PX1′, PX2, PX2′, PX3, and PX3′.

For example, the size of each of the plurality of uneven patterns 360_1, 360_2, and 360_3 can be greater than the size of the semiconductor light emitting device 150. For example, the diameter of each of the plurality of uneven patterns 360_1, 360_2, and 360_3 can be greater than the diameter of the semiconductor light emitting device 150. For example, the diameter of each of the plurality of uneven patterns 360_1, 360_2, and 360_3 can be greater than the diameter of the active layer 152 of the semiconductor light emitting device 150. Accordingly, light traveling diagonally downward from the active layer 152 of the semiconductor light emitting device 150 can be scattered and/or reflected by each of the plurality of uneven patterns 360_1, 360_2, and 360_3, thereby improving the optical viewing angle and improving light extraction efficiency. Here, improving the optical viewing angle can mean that uniform light intensity is obtained according to the optical viewing angle.

As an example, each of the plurality of uneven patterns 360_1, 360_2, and 360_3 can be disposed in a sub-pixel PX1, PX1′, PX2, PX2′, PX3, and PX3′. That is, each of the plurality of uneven patterns 360_1, 360_2, and 360_3 can be disposed in the driving region 311 and the light emitting region 312.

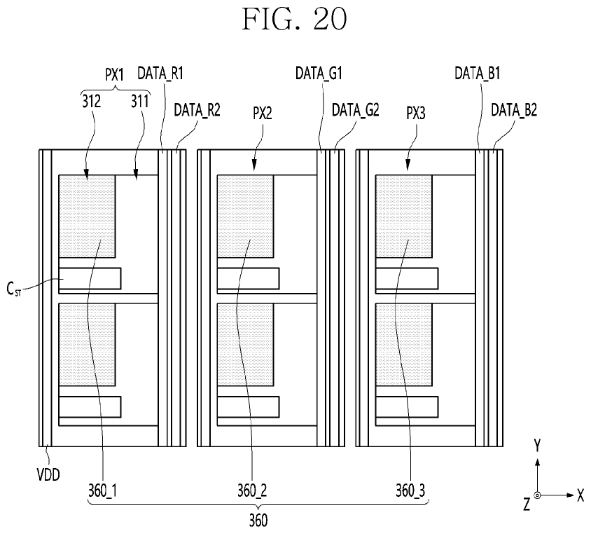

As another example, as shown in FIG. 20, the plurality of uneven patterns 360_1, 360_2, and 360_3 can be disposed in the light emitting regions 312 of the sub-pixels PX1, PX1′, PX2, PX2′, PX3, and PX3′, respectively.

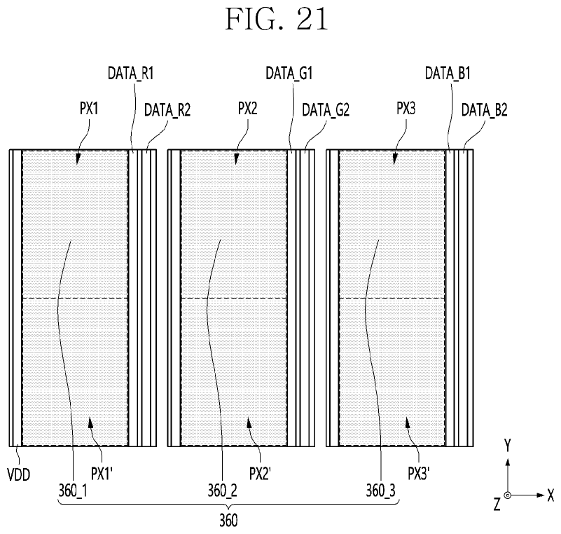

As another example, as shown in FIG. 21, the plurality of uneven patterns 360_1, 360_2, and 360_3 can be disposed in the sub-pixels PX1, PX2, and PX3 and the dummy sub-pixels PX1′, PX2′, and PX3′ defined along each stripe column, respectively.

For example, the first uneven pattern 360_1 can be disposed in the first sub-pixel PX1 and the first dummy sub-pixel PX1′ defined along the first stripe column. The first stripe column can be a column defined by the first sub-pixel PX1 and the first dummy sub-pixel PX1′ disposed along the second direction Y. For example, the first uneven pattern 360_1 can be formed integrally with the first sub-pixel PX1 and the first dummy sub-pixel PX1′ defined along the first stripe column. For example, the first uneven pattern 360_1 can be formed to be long along the first stripe column. For example, a red semiconductor light emitting device 150_R that generates red light can be disposed in the first sub-pixel PX1 and the first dummy sub-pixel PX1′ defined along the first stripe column.

For example, the second uneven pattern 360_2 can be disposed in the second sub-pixel PX2 and the second dummy sub-pixel PX2′ defined along the second stripe column. The second stripe column can be a column defined by the second sub-pixel PX2 and the second dummy sub-pixel PX2′ disposed along the second direction Y. For example, the second uneven pattern 360_2 can be formed integrally with the second sub-pixel PX2 and the second dummy sub-pixel PX2′ defined along the second stripe column. For example, the second uneven pattern 360_2 can be formed to be long along the second stripe column. For example, a green semiconductor light emitting device 150_G that generates green light can be disposed in the second sub-pixel PX2 and the second dummy sub-pixel PX2′ defined along the second stripe column.

For example, the third uneven pattern 360_3 can be disposed in the third sub-pixel PX3 and the third dummy sub-pixel PX3′ defined along the third stripe column. The third stripe column can be a column defined by the third sub-pixel PX3 and the third dummy sub-pixel PX3′ disposed along the second direction Y. For example, the third uneven pattern 360_3 can be formed integrally with the third sub-pixel PX3 and the third dummy sub-pixel PX3′ defined along the third stripe column. For example, the third uneven pattern 360_3 can be formed to be long along the third stripe column. For example, a blue semiconductor light emitting device 150_B that generates blue light can be disposed in the third sub-pixel PX3 and the third dummy sub-pixel PX3′ defined along the third stripe column.

The semiconductor light emitting device 150 generating the same color light can be disposed in the first sub-pixel PX1 and the first dummy sub-pixel PX1′, the second sub-pixel PX2 and the second dummy sub-pixel PX2′, or the third sub-pixel PX3 and the third dummy sub-pixel PX3′.

When each of the first sub-pixel PX1, the second sub-pixel PX2, and the third sub-pixel PX3 has a lighting defect, the semiconductor light emitting devices 150 disposed in each of the first dummy sub-pixel PX1′, the second dummy sub-pixel PX2′, and the third dummy sub-pixel PX3′ can emit light.

For example, the first uneven pattern 360_1 can be formed integrally with the first sub-pixel PX1 and the first dummy sub-pixel PX1′. Since the first sub-pixel PX1 and the first dummy sub-pixel PX1′ are sub-pixels having the same luminance, there is no problem even if the first electrode wire 381 on the first sub-pixel PX1 on the first uneven pattern 360_1 and the first electrode wire 381 on the first dummy sub-pixel PX1′ are electrically connected.

For example, a plurality of uneven patterns 360_1, 360_2, and 360_3 can be disposed to be spaced apart from each other between the first to third stripe columns. That is, the plurality of uneven patterns 360_1, 360_2, and 360_3 can be disposed to be spaced apart from each other between the sub-pixels, that is, between the first sub-pixel PX1 and the second sub-pixel PX2 or between the second sub-pixel PX2 and the third sub-pixel PX3 along the first direction X.

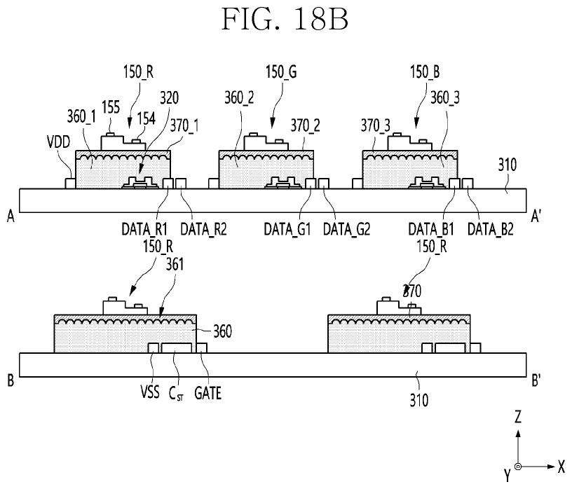

As shown in FIGS. 17A and 17B, an insulating layer 370 can be formed on the uneven layer 360.

The insulating layer 370 can comprise a plurality of insulating patterns 370_1, 370_2, and 370_3, and the insulating patterns 370_1, 370_2, and 370_3 can be disposed on the uneven patterns 360_1, 360_2, and 360_3.

For example, the insulation patterns 370_1, 370_2, and 370_3 can be disposed to be spaced apart from each other between the sub-pixels PX1, PX1′, PX2, PX2′, PX3, and PX3′.

As shown in FIG. 21, when each of the plurality of uneven patterns 360_1, 360_2, and 360_3 is integrally formed in the sub-pixels PX1, PX2, and PX3 and the dummy sub-pixels PX1′, PX2′, and PX3′, the plurality of insulating patterns 370_1, 370_2, and 370_3 can be disposed on the plurality of uneven patterns 360_1, 360_2, and 360_3 formed integrally with the sub-pixels PX1, PX2, and PX3 and the dummy sub-pixels PX1′, PX2′, and PX3′, respectively, but is not limited thereto.

The insulating layer 370 may not be separated into a plurality of insulating patterns 370_1, 370_2, and 370_3, but can be disposed on the entire area of the substrate 310. Even if the insulating layer 370 is disposed on the entire area of the substrate 310, electrical insulation is possible, so that it has nothing to do with electrical short circuit.

For example, the size of each of the plurality of insulating patterns 370_1, 370_2, and 370_3 can be the same as the size of each of the plurality of uneven patterns 360_1, 360_2, and 360_3, but is not limited thereto.

The upper surface of each of the plurality of insulating patterns 370_1, 370_2, and 370_3 can have a flat surface.

Each of the plurality of semiconductor light emitting devices 150 can be disposed in a sub-pixel PX1, PX1′, PX2, PX2′, PX3, and PX3′. At least one semiconductor light emitting device 150 can be disposed in the sub-pixels PX1, PX1′, PX2, PX2′, PX3, and PX3′. For example, the semiconductor light emitting device 150 can be a lateral-type semiconductor light emitting device, but is not limited thereto.

For example, the red semiconductor light emitting device 150_R can be disposed on the first sub-pixel PX1 and the first dummy sub-pixel PX1′. For example, the green semiconductor light emitting device 150_G can be disposed on the second sub-pixel PX2 and the second dummy sub-pixel PX2′. For example, the blue semiconductor light emitting device 150_B can be disposed on the third sub-pixel PX3 and the third dummy sub-pixel PX3.

The size of the semiconductor light emitting device 150 can be smaller than the size of the uneven layer 360 or the insulating layer 370. For example, the center of the semiconductor light emitting device 150 can coincide with the center of the uneven layer 360 or the insulating layer 370, but is not limited thereto.

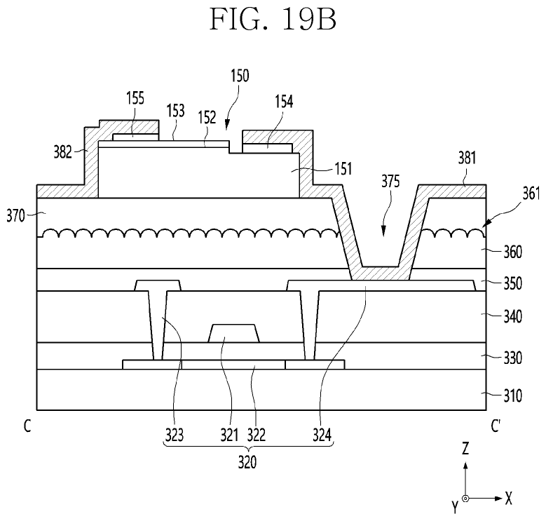

As shown in FIGS. 19A and 19B, a contact hole 375 can be formed in each sub-pixel PX1, PX1′, PX2, PX2′, PX3, and PX3′, and the first electrode wire 381 can electrically connect the transistor 320 and one side of the semiconductor light emitting device 150 through the contact hole 375. The contact hole 375 can be formed by penetrating the insulating layer 370, the uneven layer 360, and the insulating layer 350. A portion of the drain electrode 324 of the transistor 320 can be exposed through the contact hole 375, and the first electrode wiring 381 can be electrically connected to the drain electrode 324 of the transistor 320. One side of the semiconductor light emitting device 150 can be the first electrode 154.

Meanwhile, the second electrode wiring 382 can be electrically connected to the other side of the semiconductor light emitting device 150. The other side of the semiconductor light emitting device 150 can be the second electrode 155. The second electrode wiring 382 can be electrically connected to the first power line VDD, but is not limited thereto.

When the transistor 320 is a driving transistor, the gate electrode 321 of the transistor 320 can be electrically connected to the scan transistor (ST in FIG. 7), and the source electrode 323 of the scan transistor (ST in FIG. 7) 323) can be electrically connected to the data lines DATA_R1, DATA_G1 and DATA_B1. In this instance, when the scan transistor is turned on, the data signal applied to the data lines DATA_R1, DATA_G1 and DATA_B1 can be applied to the gate electrode 321 of the driving transistor 320, and the driving current corresponding to this data signal flows between the first power line VDD and the second power line VSS, the semiconductor light emitting device 150 connected between the first power line VDD and the second power source can generate light with an intensity corresponding to the driving current. When implementing a display, luminance can be determined by this light intensity. That is, as the light intensity increases, the luminance can increase, and as the light intensity decreases, the luminance can decrease.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

The embodiment can be adopted in the display field for displaying images or information.

The embodiment can be adopted in the display field for displaying images or information using a semiconductor light emitting device. The semiconductor light emitting device can be a micro-level semiconductor light emitting device or a nano-level semiconductor light emitting device.

1. A display device, comprising:
a substrate;
an uneven layer on the substrate;
an insulating layer on the uneven layer; and
a plurality of semiconductor light emitting devices on the insulating layer,
wherein the semiconductor light emitting device comprises one of a lateral-type semiconductor light emitting device and a flip-chip type semiconductor light emitting device,
wherein an upper surface of the uneven layer has roughness,
wherein a size of the uneven layer is greater than a size of the semiconductor light emitting device,
wherein the uneven layer comprises a first uneven pattern, a second uneven pattern, and a third uneven pattern,
wherein the first uneven pattern is disposed in a first sub-pixel among a plurality of sub-pixels defined along a first stripe column,
wherein the second uneven pattern is disposed in a second sub-pixel among the plurality of sub-pixels defined along a second stripe column, and
wherein the third uneven pattern is disposed on a third sub-pixel among the plurality of sub-pixels defined along a third stripe column.

2. The display device of claim 1, comprising;
a plurality of gate lines disposed along a first direction on the substrate; and
a plurality of data lines disposed along a second direction on the substrate,
wherein the plurality of sub-pixels are defined at crossings of the plurality of gate lines and the plurality of data lines, and
wherein the plurality of semiconductor light emitting devices are disposed in the plurality of sub-pixels.

3. The display device of claim 2, wherein the sub-pixel has a driving region where a transistor is disposed and a light emitting region where the semiconductor light emitting device is disposed.

4. The display device of claim 3, wherein the uneven layer comprises a plurality of uneven patterns, and
wherein the uneven pattern is disposed on the sub-pixel.

5. The display device of claim 4, wherein a size of the uneven pattern is greater than the size of the semiconductor light emitting device.

6. The display device of claim 4, wherein the uneven pattern is disposed in the light emitting region.

7. The display device of claim 4, wherein the uneven pattern is disposed in the driving region and the light emitting region.

8. The display device of claim 4, wherein the uneven patterns are disposed to be spaced apart from each other between the sub-pixels.

9. The display device of claim 4, wherein the insulating layer comprises a plurality of insulating patterns, and
wherein the insulating pattern is disposed on the uneven pattern.

10. The display device of claim 9, wherein the insulating patterns are disposed to be spaced apart from each other between the sub-pixels.

11. The display device of claim 3, comprising:
a first electrode wiring electrically connected to the transistor and one side of the semiconductor light emitting device; and
a second electrode wiring electrically connected to the other side of the semiconductor light emitting device,
wherein the first electrode wiring is disposed in a contact hole that penetrates the insulating layer and the uneven layer.

12. The display device of claim 1,
wherein the first uneven pattern is disposed in a first dummy sub-pixel defined along the first stripe column,
wherein the second uneven pattern is disposed in a second dummy sub-pixel defined along the second stripe column, and
wherein the third uneven pattern is disposed on a third dummy sub-pixel defined along the third stripe column.

13. The display device of claim 12, wherein the first uneven pattern is formed integrally with the first sub-pixel and the first dummy sub-pixel,
wherein the second uneven pattern is formed integrally with the second sub-pixel and a second dummy sub-pixel, and
wherein the third uneven pattern is formed integrally with the third sub-pixel and a third dummy sub-pixel.

14. The display device of claim 12, wherein the first to third uneven patterns are disposed to be spaced apart from each other between the first to third stripe columns.

15. The display device of claim 12, wherein the insulating layer comprises a first insulating pattern, a second insulating pattern, and a third insulating pattern,
wherein the first insulating pattern is disposed on the first uneven pattern,
wherein the second insulating pattern is disposed on the second uneven pattern, and
wherein the third insulating pattern is disposed on the third uneven pattern.

16. The display device of claim 15, wherein the first to third insulating patterns are disposed to be spaced apart from each other between the first to third stripe columns.

17. The display device of claim 1, wherein the plurality of semiconductor light emitting devices comprises a plurality of red semiconductor light emitting devices, a plurality of green semiconductor light emitting devices, and a plurality of blue semiconductor light emitting devices,
wherein the plurality of red semiconductor light emitting devices are disposed in a plurality of sub-pixels defined along the first stripe column,
wherein the plurality of green semiconductor light emitting devices are disposed in a plurality of sub-pixels defined along the second stripe column, and
wherein the plurality of blue semiconductor light emitting devices are disposed in a plurality of sub-pixels defined along the third stripe column.

18. The display device of claim 1, wherein the insulating layer is a distributed Bragg reflector (DBR) layer.

19. The display device of claim 1, wherein the insulating layer is a planarization layer having a flat upper surface.
